(19) United States
(12) Patent Application Publication
(10) Pub. No.: US 2022/0093202 A1
(43) Pub. Date: Mar. 24, 2022

(54) ADAPTIVE DRAM (DYNAMIC RANDOM ACCESS MEMORY) BURST LENGTH FOR INLINE ECC (ERROR CHECKING AND CORRECTION)

(71) Applicant: Intel Corporation, Santa Clara, CA (US)

(72) Inventors: Puneet WADHAWAN, Kanpur (IN); Sambaran MITRA, Barasat (IN)

(21) Appl. No.: 17/538,685

(22) Filed: Nov. 30, 2021

(51) Int. Cl. G11C 29/42; G11C 29/44; G11C 29/12; G11C 7/10

(52) U.S. Cl. CPC G11C 29/42; G11C 7/1039; G11C 29/1201; G11C 29/4401

(57) ABSTRACT

In a memory subsystem, the memory device and memory controller can exchange data at either a first burst length or a second burst length longer than the first burst length. The memory subsystem includes a cache or other circuitry to buffer ECC (error checking and correction) bits. The memory controller can generate a data read request to read data from memory and a separate ECC read request to read the ECC bits. The ECC cache can buffer ECC bits for multiple data read requests. The memory controller can dynamically switch the ECC read request between the first burst length and the second burst length based on usage of the ECC cache.

### FIELD

Descriptions are generally related to memory systems, and more particular descriptions are related to memory device data transfer.

### BACKGROUND

Memory subsystems that cannot use an additional memory device for ECC (error checking and correction) can apply in-band ECC (IBECC) or inline ECC. In IBECC, every read access translates into two read accesses on the memory devices: the first access for the data, and the second access for the ECC syndrome. Due to multiple requests generated from a single incoming read request, the ECC read overhead can reduce efficiency of the DRAM interface to approximately 50%.

Seeing that performance of ECC requires M ECC bits for every N data bits, where M is a number less than N, the first read access can access N data bits and the second read access can access multiples of M ECC bits. For example, assuming a system in which 8 bytes of ECC-syndrome apply to a 64-byte data cacheline, a first access obtains the 64 bytes of data, and the second access obtains 8 ECC syndromes. The ECC syndrome for only one cacheline will be used immediately, which can result in a waste of the bandwidth used to access the ECC syndromes.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1 is a block diagram of an example of a system to perform ECC data exchange at different burst lengths based on usage of an ECC cache.

FIG. 2 is a block diagram of an example of a memory controller with an ECC cache.

FIG. 3 is a block diagram of an example of a system to transfer ECC bits at different burst lengths that are dynamically selectable.

FIG. 4 is a flow diagram of an example of a process for dynamically adjusting ECC transfer burst length.

FIG. 5 is a block diagram of an example of check bit generation logic and syndrome bit generation logic to apply a matrix to perform checking and correction.

FIG. 6 is a block diagram of an example of system level error checking and correction.

FIG. 7 is a block diagram of an example of a memory subsystem in which dynamically adjusting burst rate can be implemented.

FIG. 8 is a block diagram of an example of a computing system in which dynamically adjusting burst rate can be implemented.

FIG. 9 is a block diagram of an example of a mobile device in which dynamically adjusting burst rate can be implemented.

Descriptions of certain details and implementations follow, including non-limiting descriptions of the figures, which may depict some or all examples, and well as other potential implementations.

### DETAILED DESCRIPTION

As described herein, a memory device and memory controller of a memory subsystem can exchange data at either a first burst length or a second burst length, with the second burst length being longer than the first burst length. The memory controller can generate a data read request to read data from memory and a separate ECC (error checking and correction) read request to read ECC bits corresponding to the data bits. The memory subsystem includes an ECC cache to buffer the ECC bits. The ECC cache can buffer ECC bits for multiple data read requests. The memory controller can dynamically switch the ECC read request between the first burst length and the second burst length based on usage of the ECC cache. At the second burst length, the system will access as many ECC bits as data bits, and store the extra ECC bits in the ECC cache for speculative use on subsequent reads. At the first burst length, the system will access more data bits than ECC bits, and can still buffer extra ECC bits, which will be fewer ECC bits obtained as compared to the case of using the second burst length on the ECC read request.

Consider an example of a memory subsystem with LPDDR4 (low power double data rate version 4) or LPDDR5 (low power double data rate version 5) memory devices. LPDDR systems do not use additional memory devices for ECC. Such a system can store ECC data with in-band ECC (IBECC), where every read access translates into two read accesses on the memory devices, a first for the data, and a second for the ECC syndrome.

An LPDDR system can support two different burst lengths, such as BL16 (burst length 16) and BL32 (burst length 32), where the 16 or 32 indicates how many unit intervals are the data transfer will last. A unit interval can refer to a DQS (data strobe) edge for a read or a WCK (write clock) edge for a write operation. In one example, the system can support switching between BL32 and BL16 for the ECC access, while using BL32 for data access. The system can base the determination to switch between BL32 and BL16 on use of the ECC cache, referring to how often the memory controller obtains ECC data bits from the prefetched ECC data bits in the ECC cache.

If BL32 would typically access 64 bytes of data or 64 bytes of ECC data bits, BL16 can read 32 bytes of ECC data bits, which can be four “sets” of ECC data as compared to the eight “sets” for the longer burst length. A fixed-burst length system would always obtain the larger number of ECC bits, whereas the system that allows different burst lengths can switch between obtaining more ECC data and less ECC data, based on how often it uses the data in the ECC cache. The system can continue to use BL32 or a higher burst length for data access, while dynamically switching between the higher burst length and a lower burst length for ECC access, based on use of data in the ECC cache.

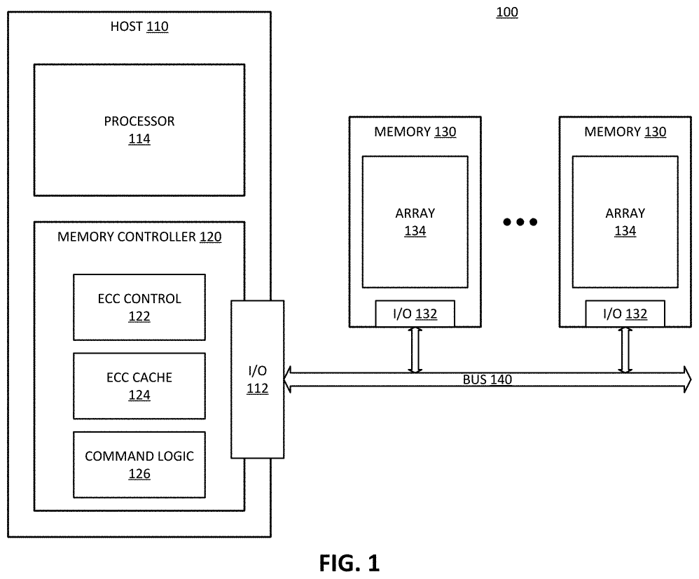

FIG. 1 is a block diagram of an example of a system to perform ECC data exchange at different burst lengths based on usage of an ECC cache. System 100 includes host 110 coupled to memory 130. System 100 includes an ECC cache and can monitor the use of the ECC cache to determine whether to use a longer or shorter burst length for inline ECC data access.

System 100 includes memory 130 that is capable of exchanging data with memory controller 120 at one of multiple burst lengths. In one example, the burst length can be dynamically changed via on-the-fly burst length control in memory 130. Such control enables the memory to be configured during runtime to use different burst lengths.

Host 110 represents a host hardware platform to which memory 130 is coupled via bus 140. Host 110 includes a host processor that generates a request for data from memory 130, represented by processor 114. Processor 114 can be or include a central processing unit (CPU), a graphics processing unit (GPU), or other processor that generates memory access commands, including a read command.

Host 110 includes memory controller 120 to manage access to memory 130. In one example, memory controller 120 is integrated onto processor 114. Memory controller 120 generates the commands to send to memory 130 to handle data requests generated by the host processor. Memory 130 represents memory devices that have memory array 134 to store data and to store ECC bits for the data. In one example, memory 130 represents dynamic random access memory (DRAM) devices compatible with a low power double data rate (LPDDR) standard.

System 100 illustrates I/O (input/output) 112 of host 110 or memory controller 120 to connect to memory 130 via bus 140. Bus 140 can represent one or more sets of signal lines to pass commands to the memory and exchange data between memory controller 120 and memory 130. Memory 130 represents individual memory devices that include I/O (input/output) 132 to connect to bus 140. Through I/O 132, memory 130 can receive commands from memory controller 120, including a read access command, and exchange data, including sending data bits and ECC bits. I/O 112 and I/O 132 represent hardware interfaces to couple the memory devices (memory 130) to memory controller 120.

In one example, memory controller 120 includes ECC control 122, which represents ECC control within host 110. ECC control 122 can perform ECC on data read from memory 130. For a write operation, ECC control 122 can generate an ECC syndrome to store with the data in memory 130. System 100 stores ECC data inline in memory 130, first writing user data with one write command, and then writing the ECC for the user data with a second write command. For a read operation, memory controller 120 generates a read command for the data (user data) and generates another read command for the ECC data.

In one example, memory controller 120 includes ECC cache 124 to store ECC data from memory 130. Because the ECC data is stored inline, the ECC read access will generate more ECC data than needed for the data. ECC cache 124 can store ECC bits for multiple data read requests. In one example, memory controller 120 only issues an ECC read command if the ECC data is not stored in ECC cache 124 (i.e., a cache miss on the ECC data). While illustrated as a cache, ECC cache 124 can represent any circuitry to buffer ECC bits. In one example, ECC cache 124 represents a cache device to store or buffer ECC bits. In one example, ECC cache 124 represents a register file to store or buffer ECC bits. A register file refers to a group of registers that store data in a structured format. In one example, ECC cache 124 represents a buffer device to store or buffer ECC bits.

In one example, memory controller 120 can control a configuration or an operational state of memory 130 to use one of multiple different burst lengths for an ECC data read. In one example, memory controller 120, through command logic 126, generates a command for memory 130 to control the operational state. Thus, in response to a command from command logic 126, system 100 can dynamically switch ECC read requests between a longer burst length and a shorter burst length based on usage of ECC cache 124.

In one example, system 100 defaults to a lower burst length for ECC data reads, and increases to a higher burst length in response to use of ECC cache 124. In one example, system 100 defaults to a higher burst length for ECC data reads, and decreases to a lower burst length in response to use of ECC cache 124. Memory controller 120 can base the burst length of an ECC read command on the use of ECC cache 124, where factors to consider can include whether a prior data read command resulted in an ECC cache hit or cache miss, how much ECC data has been evicted (discarded) from ECC cache 124 without being used by ECC control 122, what traffic profile corresponds to data traffic on accesses to memory 130, or other factors.

Factors that suggest ECC data in ECC cache 124 is being used can prompt an increase in ECC data burst length. Factors that suggest ECC data is being discarded from ECC cache 124 without being used can prompt a decrease in ECC data burst length. In one example, memory controller 120 dynamically switches from the shorter burst length to the longer burst length in response to an increase in ECC cache hit rate. In one example, memory controller 120 dynamically switches from the longer burst length to the shorter burst length in response to a decrease in ECC cache hit rate.

As such, system 100 applies a dynamic and adaptive use of burst length for ECC data accesses to memory 130. Thus, system 100 can dynamically adapt to various traffic profiles and adaptively extract the efficiency of memory 130. In one example, system 100 can hide the microarchitectural latency associated with reads behind access to ECC cache 124 for ECC access. Hiding the latency enables the operation of ECC cache 124 without incurring a performance disadvantage over a system that simply uses the ECC data in realtime.

Command logic 126 of memory controller 120 represents logic or control to generate access commands to send to memory 130. In one example, command logic 126 generates and sends a data read request to read data from array 134, and generates and sends a separate ECC read request to read the ECC bits from array 134.

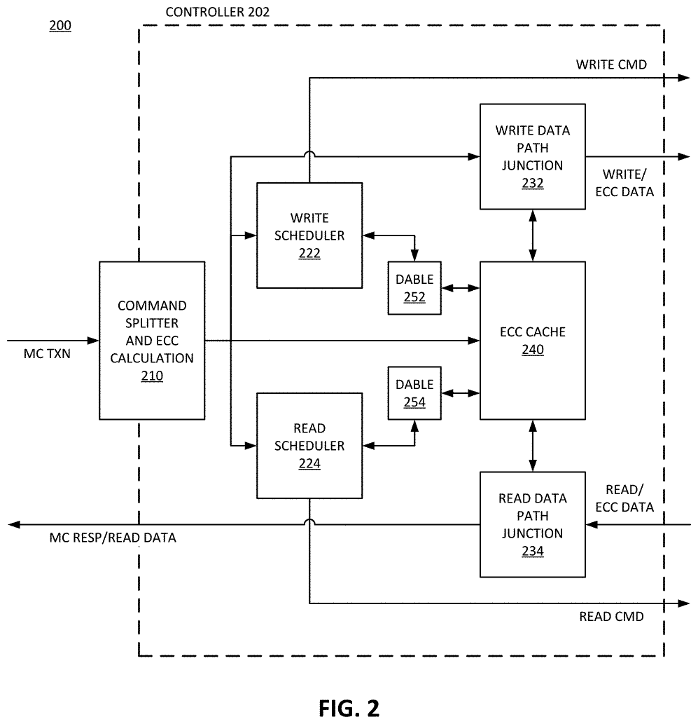

FIG. 2 is a block diagram of an example of a memory controller with an ECC cache. System 200 represents a system in which a memory controller can be included. Controller 202 represents the controller. System 200 represents a system in accordance with an example of system 100. System 200 represents a system in which inline ECC can be used. System 200, through controller 202, can implement a dynamic and adaptive burst length enhancer (DABLE) architecture.

Controller 202 is represented in system 200 as an example; one or more elements within the dashed line boundary of controller 202 can be considered outside a memory controller. Thus, controller 202 is representative of the operations associated with the memory controller without necessarily being indicating the specific components within a memory controller.

System 200 includes command splitter and ECC calculation 210 (hereinafter “block 210”), which can be part of controller 202 or outside of controller 202. Block 210 receives a memory controller transaction (MC TXN) from the host processor. For writes, the memory controller transaction includes the command and the write data information. For reads, the memory controller transaction only includes the read command information. In system 200 with IBECC, read and write commands need to be split into two read commands or two write commands, respectively. Block 210 splits the transactions and generates the appropriate memory access commands. For a write transaction, block 210 can calculate the ECC information for the original write data.

For a write transaction, the data and command flow can be in accordance with the following. Block 210 can provide the write command information to write scheduler 222 and the write data to write data path junction 232. Write scheduler 222 represents the write scheduling logic of controller 202. Write scheduler 222 can drive the command and address (CA) signal lines that couple with the memory devices with the write command (CMD).

Write data path junction 232 stores the write data for the write command. Working with write scheduler 222 and ECC cache 240, write data path junction 232 can drive the DQ (data) lines that couple with the memory devices. Write data path junction 232 can drive the DQ signal lines with the write data and the ECC data.

For a read transaction, the data and command flow can be in accordance with the following. Block 210 can provide the read command information to read scheduler 224, which represent the read scheduling logic of controller 202. Read scheduler 224 can drive the CA signal lines that couple with the memory devices with the read command (CMD). Although system 200 represents the write command and read command separately, the CA signal lines are the same physical bus used to send commands for both write transactions and read transactions.

In response to the read command, the memory can send read and ECC data back to read data path junction 234. Although system 200 represents the write data and read data separately, the DQ signal lines are the same physical bus used to exchange data for write transactions and for read transactions. In one example, read data path junction 234 feeds the ECC data into ECC cache 240. Read data path junction 234 also sends the data back to the requester through memory controller response (MC RESP)/read data lines.

ECC cache 240 represents a cache and cache controller for ECC data to store in controller 202. ECC cache 240 could be referred to as an ECC syndrome cache. The ECC data is cached in ECC cache 240 to apply for different read transactions. In one example, ECC cache 240 stores the ECC data coming through block 210 for write transactions. ECC cache 240 can work with write scheduler 222 and write data path junction 232 to drive ECC data to the memory for write transactions. In one example, ECC cache 240 stores the ECC data coming from memory in response to an ECC read transaction.

In one example, controller 202 includes DABLE (dynamic and adaptive burst length enhancer) 252 and DABLE 254. DABLE 252 can interconnect write scheduler 222 with ECC cache 240. DABLE 254 can interconnect read scheduler 224 with ECC cache 240. While system 200 illustrates separate DABLE blocks, DABLE 252 and DABLE 254 can apply the same logic for determining whether to increase or decrease the burst length for ECC reads. DABLE 252 can indicate a dynamic change of burst length to write scheduler 222, which can then generate one or more commands to trigger the memory to change the burst length. DABLE 254 can indicate the dynamic change of burst length to read scheduler 224, which can then schedule the command based on the timing associated with the applied burst length. DABLE 252 and DABLE 254 can be collectively referred to as DABLE logic or a DABLE block or simply as DABLE.

System 200 can include DABLE as a pluggable micro-block. The micro-block can refer to a circuit included in controller 202. The micro-block can refer to firmware code to be executed by control logic of controller 202. As a pluggable micro-block, DABLE can be included or excluded from a controller design. DABLE is non-intrusive in the controller architecture.

In one example, DABLE implements threshold detection to detect the spatial locality in the memory access requests. In one example, system 200 has a default burst length for data reads and a default burst length for ECC reads. The default burst length for ECC reads can be different than the default burst length for data reads. In one example, DABLE detects spatial locality in terms of a miss rate of ECC cache 240. In one example, when the cache miss rate indicates a high spatial locality (e.g., above a threshold) in the address streams, DABLE can trigger controller 202 to dynamically change the ECC burst length to a longer burst. In one example, when the spatial locality is low (e.g., below a threshold), DABLE can trigger controller 202 to dynamically change the ECC burst length to a shorter burst.

System 200 can implement threshold detection for DABLE in accordance with one or multiple approaches. In one example, the threshold for changing ECC burst length is a product of cache miss rate and PercentileECC, where PercentileECC represents a percentile or percentage of ECC requests sent to memory with respect to the total number of memory access requests sent. In one example, the threshold for changing ECC burst length is based on ECC usage efficiency bits (UsageEffECC), where UsageEffECC represents a usage of ECC bytes cached in ECC cache 240. In one example, the ECC Usage efficiency parameter has a value UsageEffiECC [(N−1):0], which can be incremented when any byte available in a cacheline is accessed.

In one example, the threshold for changing ECC burst length is based on ECC cache miss rate (Rmiss), which represents a rate at which a new data request finds its ECC available in ECC cache 240. System 200 can base the change of ECC burst length on any of these parameters, other parameters, a combination of these parameters, a combination of one or more of these parameters with one or more other parameters, all of these parameters, or other combination.

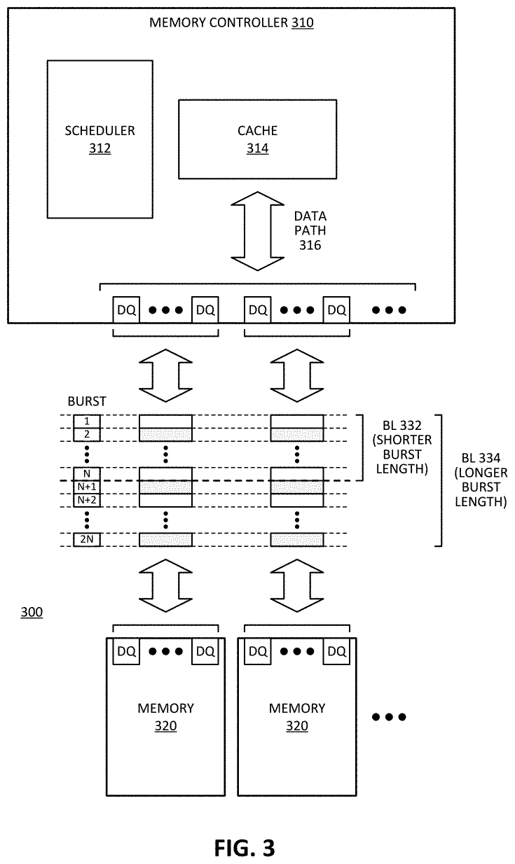

FIG. 3 is a block diagram of an example of a system to transfer ECC bits at different burst lengths that are dynamically selectable. System 300 represents a system in accordance with an example of system 200 or an example of system 100. System 300 illustrates memory coupled to a host. The host is represented by memory controller 310 coupled to memory 320. Memory controller 310 includes interconnect hardware and driver/receiver hardware to provide an interconnection between memory controller 310 and memory 320.

Memory 320 includes parallel memory resources. Memory controller 310 controls access to memory 320. In one example, memory 320 represents low power double data rate (LPDDR) dynamic random access memory (DRAM) devices that can switch between different burst lengths for data transfer with memory controller 310.

Memory controller 310 includes scheduler 312, which represents one or more schedulers in the memory controller, such as a read scheduler and a write scheduler. In one example, the read scheduler and the write scheduler are part of the same scheduler. Scheduler 312 enables memory controller 310 to schedule read commands and write commands based on the timing when read data will be received from memory 320 in response to read commands or when write data should be sent to memory 320 with write commands.

System 300 represents the interface hardware of memory controller 310 by the DQ (data) pads, which correspond with DQ pads on the separate memory devices of memory 320. It will be understood that memory 320 share a command bus (not specifically shown), and have unique DQ signal lines. Memory 320 can have, for example, a ×4, ×8, ×16, ×32 DQ interface, or some other interface width. The different interface widths refer to how many DQ signal lines are included in the interface.

In one example, memory controller 310 includes cache 314, which represents an ECC syndrome cache to cache ECC data on a two-operation read or two-operation write, where data is exchanged with one access command, and a different (typically, but not necessarily, subsequent) access command exchanges ECC data. Memory controller 310 includes data path 316 from the DQ pads to cache 314.

System 300 illustrates two different burst lengths: BL (burst length) 332 and BL (burst length) 334. As illustrated, BL 332 is a shorter burst length and BL 334 is a longer burst length. System 300 specifically illustrates BL 332 to be half of BL 334, with BL 332 spanning N transfer cycles and BL 334 spanning 2N transfer cycles. N is typically a binary number, such as 8 or 16. In one specific implementation, N is 16 and 2N is 32, making BL 332 equal to BL16 and BL 334 equal to BL32. Instead of referring to N and 2N, system 300 can be expressed as N and N/2, with N=32 and N/2=16, for the example given above.

In one example, memory controller 310 dynamically and adaptively switches between BL 332 and BL 334 for the exchange of ECC data bits. The dynamic switching can be in accordance with any example herein. In one example, memory controller 310 and memory 320 exchange user data at BL 334 for all data transfers and exchange ECC data at BL 332 as a default. Memory controller 310 can determine to exchange ECC data at BL 334 based on usage of ECC data from cache 314.

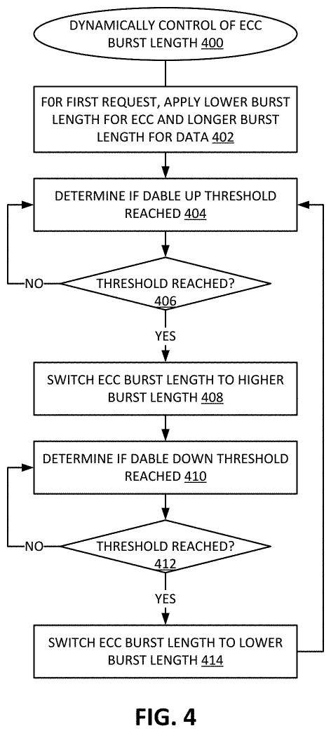

FIG. 4 is a flow diagram of an example of a process for dynamically adjusting ECC transfer burst length. Process 400 represents an example of a process that can be executed by a system in accordance with system 200.

In one example, for a first access request, the memory controller applies a lower burst length for ECC and a longer burst length for data, at 402. The longer burst length for data can be a default. The shorter burst length for ECC can also be a default.

In one example, the memory controller determines if a DABLE-Up threshold is reached, at 404. The DABLE-Up threshold represents a threshold to indicate that the shorter ECC burst length should be increased to a higher burst length.

In one example, the threshold is an ECC cache miss rate. Monitoring the miss rate can detect spatial locality. If the threshold is not reached (e.g., low spatial locality because it is below the threshold), at 406 NO branch, the memory controller can continue to monitor for the threshold or a condition to determine to increase the ECC burst length.

If the threshold has been reached (e.g., high spatial locality because it is above the threshold), at 406 YES branch, in one example, the memory controller switches the ECC burst length to a higher burst length, at 408. When operating at the higher burst length, the memory controller can determine if a threshold or a condition is reached that indicates the ECC burst length should be reduced.

In one example, the memory controller determines whether a DABLE-Down threshold has been reached, at 410. In one example, similar to the DABLE-Up threshold, the DABLE-Down threshold can indicate a change in application runtime behavior that changes to a lower spatial locality.

If the DABLE-Down threshold has not been reached, at 412 NO branch, the memory controller can continue to monitor for a threshold or condition that indicates moving to a lower threshold while continuing to operate at the higher threshold. If the threshold has been reached, at 412 YES branch, in one example, the memory controller switches the ECC burst length to the lower burst length, at 414, and monitors to determine if the threshold should be increased, at 404.

It will be understood that process 400 illustrates an example for two burst lengths, a higher burst length and a lower burst length. Process 400 can be applied to additional burst lengths with the application of additional thresholds or different conditions that indicate changing from one level to the one above or to the one below.

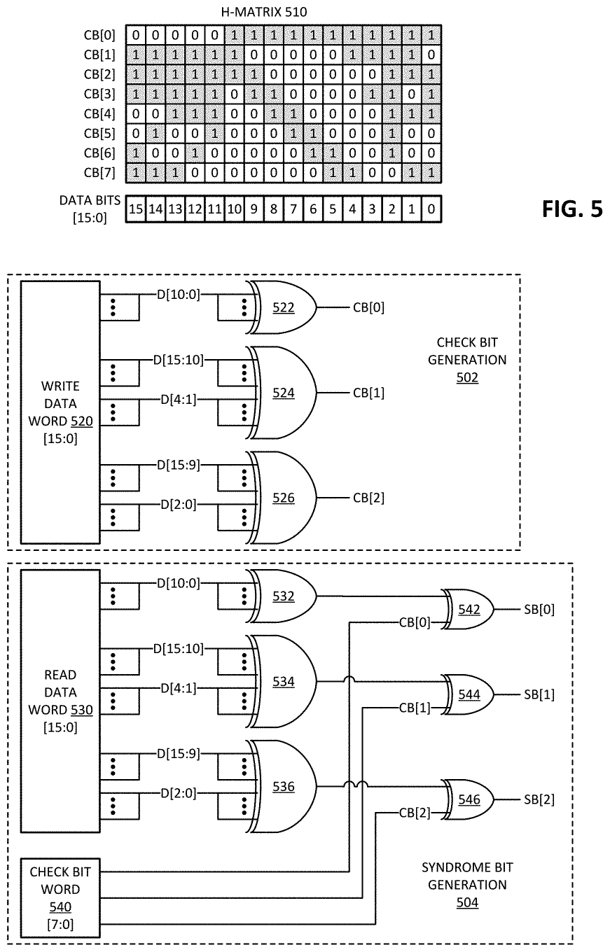

FIG. 5 is a block diagram of an example of check bit generation logic and syndrome bit generation logic to apply a matrix to perform checking and correction. H matrix 510 represents an example of 16 bits of a code matrix for use with on-device ECC. It will be understood that a typical operational code word in modern computing systems includes more than 16 bits. However, the 16-bit H-matrix illustrates principles of ECC operation for either on-die ECC to be used in on-memory error checking and correction in accordance with any example herein or for system level ECC by the memory controller or error control in accordance with any example herein.

Matrix 510 can be part of an SEC Hamming code, such as a hamming code for a 128-bit code word. Matrix 510 illustrates only 16 codes, one code bit for each data bit [15:0]. In one example, every code of matrix 510 corresponds to one data bit. In the example illustrated, each code includes 8 check bits CB[0:7]. When a syndrome is computed from the data word and check bits stored in the memory, the ECC engine can determine if the syndrome corresponds to one of the codes in matrix 510. If the ECC engine determines a syndrome matches with one of the codes, the ECC engine toggles the corresponding data bit to correct an error. Examples of check bit generation and syndrome bit generation are illustrated.

Check bit generation logic 502 represents logic to perform ECC operations to generate check bits. Syndrome bit generation logic 504 represents logic to perform ECC operations to generate syndrome bits to compare against the check bit. For purposes of illustration in the drawing, only logic related to check bits CB[0:2] are illustrated, and correspondingly, only syndrome bits SB[0:2] are illustrated.

As illustrated, the syndrome can be completely encoded in the ECC logic for the check bit generation and syndrome bit generation. In one example, check bit generation 502 includes XOR gates to receive write data word 520 and perform XOR operations for the one-bits of the code. For example, generation of CB[0] with respect to 16 code word bits illustrated, bits D[10:0] are all ones, whereas bits D[15:11] are zeros. Thus, in one example, computation of CB[0] includes the XOR operation with XOR 522 of bits D[10:0] of the code word. Similarly, generation of the syndrome bit SB[0] includes logic to receive read data word 530 and perform XOR operation with XOR 532 of bits D[10:0] of the read data code word. The output of XOR 532 is then XORed with XOR 542 with CB[0] to generate SB[0].

It will be understood that as a technical matter, a true XOR operation can only exist for two inputs, where an output is one if and only if only one of the inputs is one. However, it is common convention to represent a cascade of XOR operations as a multi-input XOR (meaning a number of inputs greater than 2), such as XOR 522 for CB[0] and XOR 532 for SB[0]. The XOR operation has a commutative property, and the XORing of multiple pairs of inputs, and then the series XORing of the outputs of those operations can be interchanged in any order with the same result. Thus, the XOR operations have the practical effect of modulo 2 addition, which is also equivalent to odd parity detection. Odd parity detection provides a ‘1’ as the output when there is an odd number of ones among the inputs, and an output zero when there is an even number of ones among the inputs.

In another example, generation of CB[1] with respect to the 16 code word bits illustrated, bits D[15:10] and D[4:1] are ones, and bits D[9:5] and D[0] are zeros. XOR 524 computes CB[1] from the one bits. Similarly, for the generation of CB[2], bits D[15:9] and D[2:0] are ones, and bits D[8:3] are zeros. XOR 526 computes CB[2] from the one bits.

Syndrome bit generation 504 represents logic to receive read data word 530 and check bit word 540, and generate the syndrome bits by comparison of the CB computation with the stored check bits. Similarly, syndrome bit generation of SB[1] with respect to the 16 code word bits illustrated, XOR 534 computes an XOR of D[15:10] and D[4:1], and then XOR 544 computes SB[1] by XOR of CB[1] with the output of XOR 534. Similarly, syndrome bit generation of SB[2] with respect to the 16 code word bits illustrated, XOR 536 computes an XOR of D[15:9] and D[2:0], and then XOR 546 computes SB[2] by XOR of CB[2] with the output of XOR 536. Based on the determination of the check bits and syndrome bits, the system can identify errors and potentially flip bits, e.g., for a bit or column of CB[7:0] found to match with the syndrome bits.

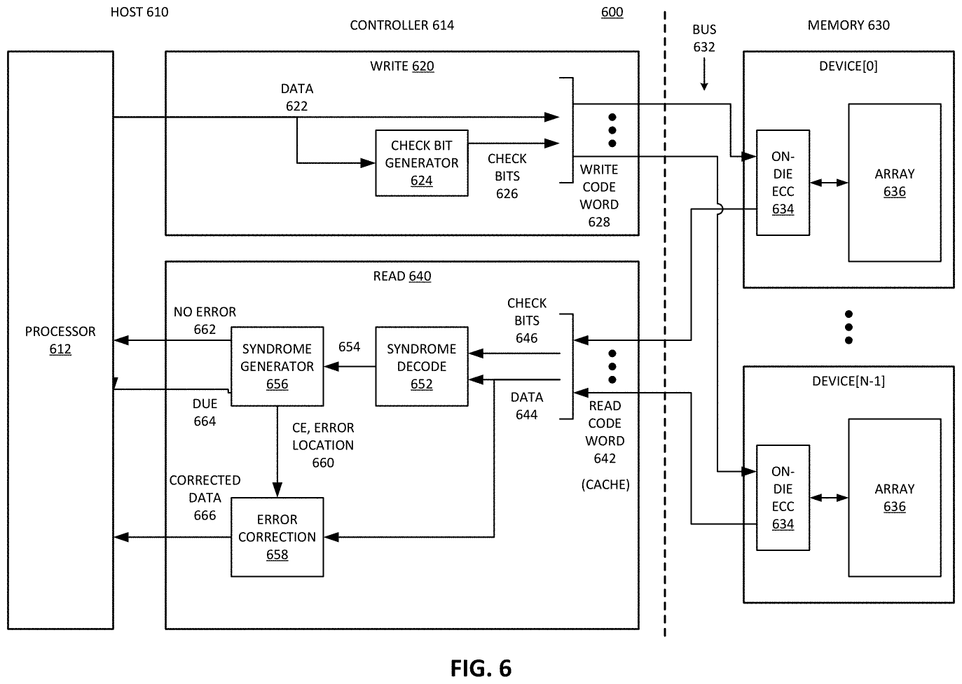

FIG. 6 is a block diagram of an example of system level error checking and correction. System 600 provides an example of system level ECC circuitry for a system in accordance with any example of host side or memory controller ECC herein. Host 610 includes controller 614 or equivalent or alternative logic or circuit or component that manages access to memory 630. Controller 614 performs external ECC on data read from memory 630. In one example, memory 630 implements on-die ECC 634 to check and correct data from array 636 prior to sending the data over bus 632 to host 610.

Host 610 includes processor 612 to execute operations that will generate requests for data stored in array 636 of memory 630. In response to a request to write data, controller 614 can generate a write command through write path 620. For a read request, controller 614 receives read data through read path 640.

Write path 620 represents a path for data written from processor 612 to memory 630. Processor 612 provides data 622 for writing to memory 630. In one example, controller 614 generates check bits 626 with check bit generator 624 to store with the data in memory. Check bits 626 can be referred to as ECC bits, and enable error correction for an error that might occur in the writing to and reading from the memory array(s). Data 622 and check bits 626 can be included as write code word 628, which is written to memory 630, over data bus 632 into array 636.

Read path 640 represents a path for data read from memory 630 to host 610. In one example, at least certain hardware components of write path 620 and read path 640 are the same hardware. In one example, memory 630 fetches the data in response to a Read command from host 610. Read code word 642 represents the data and check bits that were stored in array 636. Data 644 and check bits 646 represent the data and check bits of read code word 642. Read code word 642 represents a codeword made up of data from Device[0:(N−1)]. In one example, these correspond, respectively, to data 622 and check bits 626 written in write path 620 to the same address of the read command.

Read path 640 includes syndrome decode 652 to apply H matrix computations on data 644 and check bits 646 to detect errors in the read data. Syndrome decode 652 can generate syndrome 654 for use in generating appropriate error information for the read data. Data 644 can also be forwarded to error correction 658 for correction of a detected error.

In one example, syndrome decode 652 passes syndrome 654 to syndrome generator 656 to generate an error vector. In one example, check bit generator 624 and syndrome generator 656 are fully specified by a corresponding H matrix. In one example, if there are no errors in the read data (e.g., zero syndrome 654), syndrome generator 656 generates a no error signal 662. In one example, if there are multiple errors in the read data (e.g., non-zero syndrome 654 that does not match any of the columns in a corresponding H matrix), syndrome generator 656 generates a DUE (detected uncorrected error) signal 664. DUE signal 664 can indicate a multibit error that was not able to be corrected by the application of ECC.

In one example, if there is a single bit error (e.g., non-zero syndrome 654 that matches one of the columns of a corresponding H matrix), syndrome generator 656 can generate a CE (corrected error) signal with error location 660, which is a corrected error indication to error correction logic 658. Error correction 658 can apply the corrected error to the specified location in data 644 to generate corrected data 666 for output to provide to processor 612.

In accordance with an example of system 100, system 200, or system 300, system 600 can send write code word 628 as a separate write transaction. Controller 614 can receive read code word 642 into an ECC cache, receiving the ECC bits over bus 632 at a dynamically adaptable burst length, based on usage of the cache.

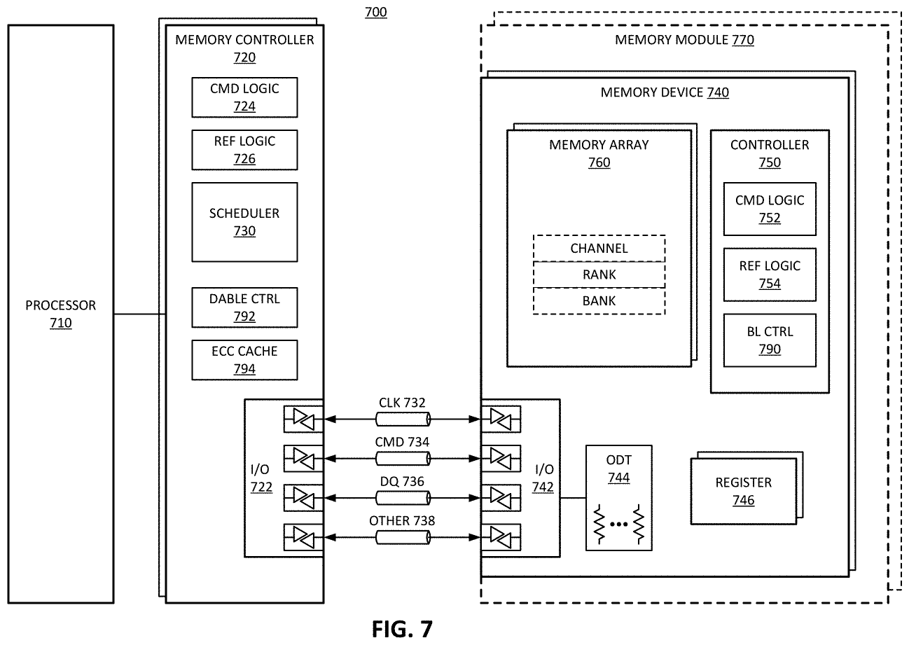

FIG. 7 is a block diagram of an example of a memory subsystem in which dynamically adjusting burst rate can be implemented. System 700 includes a processor and elements of a memory subsystem in a computing device. System 700 is a system in accordance with an example of system 100, system 200, or system 300.

In one example, controller 750 of memory device 740 includes BL control (CTRL) 790 to control the burst length of data exchanged with memory controller 720. In one example, memory controller 720 includes ECC cache 794 to cache ECC data for a two-operation memory access, where ECC data is stored inline. In one example, memory controller 720 includes DABLE control (CTRL) 792 to manage ECC cache 794. DABLE control 792 can determine whether to change a burst length for the exchange of ECC data based on usage of ECC cache 794. The determination can be in accordance with any example herein.

Processor 710 represents a processing unit of a computing platform that may execute an operating system (OS) and applications, which can collectively be referred to as the host or the user of the memory. The OS and applications execute operations that result in memory accesses. Processor 710 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 700 can be implemented as an SOC (system on a chip), or be implemented with standalone components.

Reference to memory devices can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random-access memory), or some variant such as synchronous DRAM (SDRAM). A memory subsystem as described herein may be compatible with a number of memory technologies, such as DDR4 (double data rate version 4, JESD79-4, originally published in September 2012 by JEDEC (Joint Electron Device Engineering Council, now the JEDEC Solid State Technology Association), LPDDR4 (low power DDR version 4, JESD209-4, originally published by JEDEC in August 2014), WIO2 (Wide I/O 2 (WideIO2), JESD229-2, originally published by JEDEC in August 2014), HBM (high bandwidth memory DRAM, JESD235A, originally published by JEDEC in November 2015), DDR5 (DDR version 5, originally published by JEDEC in July 2020), LPDDR5 (LPDDR version 5, JESD209-5, originally published by JEDEC in February 2019), HBM2 ((HBM version 2), currently in discussion by JEDEC), or others or combinations of memory technologies, and technologies based on derivatives or extensions of such specifications.

Memory controller 720 represents one or more memory controller circuits or devices for system 700. Memory controller 720 represents control logic that generates memory access commands in response to the execution of operations by processor 710. Memory controller 720 accesses one or more memory devices 740. Memory devices 740 can be DRAM devices in accordance with any referred to above. In one example, memory devices 740 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one example, settings for each channel are controlled by separate mode registers or other register settings. In one example, each memory controller 720 manages a separate memory channel, although system 700 can be configured to have multiple channels managed by a single controller, or to have multiple controllers on a single channel. In one example, memory controller 720 is part of host processor 710, such as logic implemented on the same die or implemented in the same package space as the processor.

Memory controller 720 includes I/O interface logic 722 to couple to a memory bus, such as a memory channel as referred to above. I/O interface logic 722 (as well as I/O interface logic 742 of memory device 740) can include pins, pads, connectors, signal lines, traces, or wires, or other hardware to connect the devices, or a combination of these. I/O interface logic 722 can include a hardware interface. As illustrated, I/O interface logic 722 includes at least drivers/transceivers for signal lines. Commonly, wires within an integrated circuit interface couple with a pad, pin, or connector to interface signal lines or traces or other wires between devices. I/O interface logic 722 can include drivers, receivers, transceivers, or termination, or other circuitry or combinations of circuitry to exchange signals on the signal lines between the devices. The exchange of signals includes at least one of transmit or receive. While shown as coupling I/O 722 from memory controller 720 to I/O 742 of memory device 740, it will be understood that in an implementation of system 700 where groups of memory devices 740 are accessed in parallel, multiple memory devices can include I/O interfaces to the same interface of memory controller 720. In an implementation of system 700 including one or more memory modules 770, I/O 742 can include interface hardware of the memory module in addition to interface hardware on the memory device itself. Other memory controllers 720 will include separate interfaces to other memory devices 740.

The bus between memory controller 720 and memory devices 740 can be implemented as multiple signal lines coupling memory controller 720 to memory devices 740. The bus may typically include at least clock (CLK) 732, command/address (CMD) 734, and write data (DQ) and read data (DQ) 736, and zero or more other signal lines 738. In one example, a bus or connection between memory controller 720 and memory can be referred to as a memory bus. In one example, the memory bus is a multi-drop bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one example, independent channels have different clock signals, C/A buses, data buses, and other signal lines. Thus, system 700 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 720 and memory devices 740. An example of a serial bus technology is 8B10B encoding and transmission of high-speed data with embedded clock over a single differential pair of signals in each direction. In one example, CMD 734 represents signal lines shared in parallel with multiple memory devices. In one example, multiple memory devices share encoding command signal lines of CMD 734, and each has a separate chip select (CS_n) signal line to select individual memory devices.

It will be understood that in the example of system 700, the bus between memory controller 720 and memory devices 740 includes a subsidiary command bus CMD 734 and a subsidiary bus to carry the write and read data, DQ 736. In one example, the data bus can include bidirectional lines for read data and for write/command data. In another example, the subsidiary bus DQ 736 can include unidirectional write signal lines for write and data from the host to memory, and can include unidirectional lines for read data from the memory to the host. In accordance with the chosen memory technology and system design, other signals 738 may accompany a bus or sub bus, such as strobe lines DQS. Based on design of system 700, or implementation if a design supports multiple implementations, the data bus can have more or less bandwidth per memory device 740. For example, the data bus can support memory devices that have either a ×4 interface, a ×8 interface, a ×16 interface, or other interface. The convention “×W,” where W is an integer that refers to an interface size or width of the interface of memory device 740, which represents a number of signal lines to exchange data with memory controller 720. The interface size of the memory devices is a controlling factor on how many memory devices can be used concurrently per channel in system 700 or coupled in parallel to the same signal lines. In one example, high bandwidth memory devices, wide interface devices, or stacked memory configurations, or combinations, can enable wider interfaces, such as a ×128 interface, a ×256 interface, a ×512 interface, a ×1024 interface, or other data bus interface width.

In one example, memory devices 740 and memory controller 720 exchange data over the data bus in a burst, or a sequence of consecutive data transfers. The burst corresponds to a number of transfer cycles, which is related to a bus frequency. In one example, the transfer cycle can be a whole clock cycle for transfers occurring on a same clock or strobe signal edge (e.g., on the rising edge). In one example, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length eight (BL8), and each memory device 740 can transfer data on each UI. Thus, a ×8 memory device operating on BL8 can transfer 74 bits of data (8 data signal lines times 7 data bits transferred per line over the burst). It will be understood that this simple example is merely an illustration and is not limiting.

Memory devices 740 represent memory resources for system 700. In one example, each memory device 740 is a separate memory die. In one example, each memory device 740 can interface with multiple (e.g., 2) channels per device or die. Each memory device 740 includes I/O interface logic 742, which has a bandwidth determined by the implementation of the device (e.g., ×16 or ×8 or some other interface bandwidth). I/O interface logic 742 enables the memory devices to interface with memory controller 720. I/O interface logic 742 can include a hardware interface, and can be in accordance with I/O 722 of memory controller, but at the memory device end. In one example, multiple memory devices 740 are connected in parallel to the same command and data buses. In another example, multiple memory devices 740 are connected in parallel to the same command bus, and are connected to different data buses. For example, system 700 can be configured with multiple memory devices 740 coupled in parallel, with each memory device responding to a command, and accessing memory resources 760 internal to each. For a Write operation, an individual memory device 740 can write a portion of the overall data word, and for a Read operation, an individual memory device 740 can fetch a portion of the overall data word. The remaining bits of the word will be provided or received by other memory devices in parallel.

In one example, memory devices 740 are disposed directly on a motherboard or host system platform (e.g., a PCB (printed circuit board) on which processor 710 is disposed) of a computing device. In one example, memory devices 740 can be organized into memory modules 770. In one example, memory modules 770 represent dual inline memory modules (DIMMs). In one example, memory modules 770 represent other organization of multiple memory devices to share at least a portion of access or control circuitry, which can be a separate circuit, a separate device, or a separate board from the host system platform. Memory modules 770 can include multiple memory devices 740, and the memory modules can include support for multiple separate channels to the included memory devices disposed on them. In another example, memory devices 740 may be incorporated into the same package as memory controller 720, such as by techniques such as multi-chip-module (MCM), package-on-package, through-silicon via (TSV), or other techniques or combinations. Similarly, in one example, multiple memory devices 740 may be incorporated into memory modules 770, which themselves may be incorporated into the same package as memory controller 720. It will be appreciated that for these and other implementations, memory controller 720 may be part of host processor 710.

Memory devices 740 each include one or more memory arrays 760. Memory array 760 represents addressable memory locations or storage locations for data. Typically, memory array 760 is managed as rows of data, accessed via wordline (rows) and bitline (individual bits within a row) control. Memory array 760 can be organized as separate channels, ranks, and banks of memory. Channels may refer to independent control paths to storage locations within memory devices 740. Ranks may refer to common locations across multiple memory devices (e.g., same row addresses within different devices) in parallel. Banks may refer to sub-arrays of memory locations within a memory device 740. In one example, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one example, memory devices 740 include one or more registers 744. Register 744 represents one or more storage devices or storage locations that provide configuration or settings for the operation of the memory device. In one example, register 744 can provide a storage location for memory device 740 to store data for access by memory controller 720 as part of a control or management operation. In one example, register 744 includes one or more Mode Registers. In one example, register 744 includes one or more multipurpose registers. The configuration of locations within register 744 can configure memory device 740 to operate in different “modes,” where command information can trigger different operations within memory device 740 based on the mode. Additionally or in the alternative, different modes can also trigger different operation from address information or other signal lines depending on the mode. Settings of register 744 can indicate configuration for I/O settings (e.g., timing, termination or ODT (on-die termination) 746, driver configuration, or other I/O settings).

In one example, memory device 740 includes ODT 746 as part of the interface hardware associated with I/O 742. ODT 746 can be configured as mentioned above, and provide settings for impedance to be applied to the interface to specified signal lines. In one example, ODT 746 is applied to DQ signal lines. In one example, ODT 746 is applied to command signal lines. In one example, ODT 746 is applied to address signal lines. In one example, ODT 746 can be applied to any combination of the preceding. The ODT settings can be changed based on whether a memory device is a selected target of an access operation or a non-target device. ODT 746 settings can affect the timing and reflections of signaling on the terminated lines. Careful control over ODT 746 can enable higher-speed operation with improved matching of applied impedance and loading. ODT 746 can be applied to specific signal lines of I/O interface 742, 722 (for example, ODT for DQ lines or ODT for C/A lines), and is not necessarily applied to all signal lines.

Memory device 740 includes controller 750, which represents control logic within the memory device to control internal operations within the memory device. For example, controller 750 decodes commands sent by memory controller 720 and generates internal operations to execute or satisfy the commands. Controller 750 can be referred to as an internal controller, and is separate from memory controller 720 of the host. Controller 750 can determine what mode is selected based on register 744, and configure the internal execution of operations for access to memory resources 760 or other operations based on the selected mode. Controller 750 generates control signals to control the routing of bits within memory device 740 to provide a proper interface for the selected mode and direct a command to the proper memory locations or addresses. Controller 750 includes command logic 752, which can decode command encoding received on command and address signal lines. Thus, command logic 752 can be or include a command decoder. With command logic 752, memory device can identify commands and generate internal operations to execute requested commands.

Referring again to memory controller 720, memory controller 720 includes command (CMD) logic 724, which represents logic or circuitry to generate commands to send to memory devices 740. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 740, memory controller 720 can issue commands via I/O 722 to cause memory device 740 to execute the commands. In one example, controller 750 of memory device 740 receives and decodes command and address information received via I/O 742 from memory controller 720. Based on the received command and address information, controller 750 can control the timing of operations of the logic and circuitry within memory device 740 to execute the commands. Controller 750 is responsible for compliance with standards or specifications within memory device 740, such as timing and signaling requirements. Memory controller 720 can implement compliance with standards or specifications by access scheduling and control.

Memory controller 720 includes scheduler 730, which represents logic or circuitry to generate and order transactions to send to memory device 740. From one perspective, the primary function of memory controller 720 could be said to schedule memory access and other transactions to memory device 740. Such scheduling can include generating the transactions themselves to implement the requests for data by processor 710 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 720 typically includes logic such as scheduler 730 to allow selection and ordering of transactions to improve performance of system 700. Thus, memory controller 720 can select which of the outstanding transactions should be sent to memory device 740 in which order, which is typically achieved with logic much more complex that a simple first-in first-out algorithm. Memory controller 720 manages the transmission of the transactions to memory device 740, and manages the timing associated with the transaction. In one example, transactions have deterministic timing, which can be managed by memory controller 720 and used in determining how to schedule the transactions with scheduler 730.

In one example, memory controller 720 includes refresh (REF) logic 726. Refresh logic 726 can be used for memory resources that are volatile and need to be refreshed to retain a deterministic state. In one example, refresh logic 726 indicates a location for refresh, and a type of refresh to perform. Refresh logic 726 can trigger self-refresh within memory device 740, or execute external refreshes which can be referred to as auto refresh commands) by sending refresh commands, or a combination. In one example, controller 750 within memory device 740 includes refresh logic 754 to apply refresh within memory device 740. In one example, refresh logic 754 generates internal operations to perform refresh in accordance with an external refresh received from memory controller 720. Refresh logic 754 can determine if a refresh is directed to memory device 740, and what memory resources 760 to refresh in response to the command.

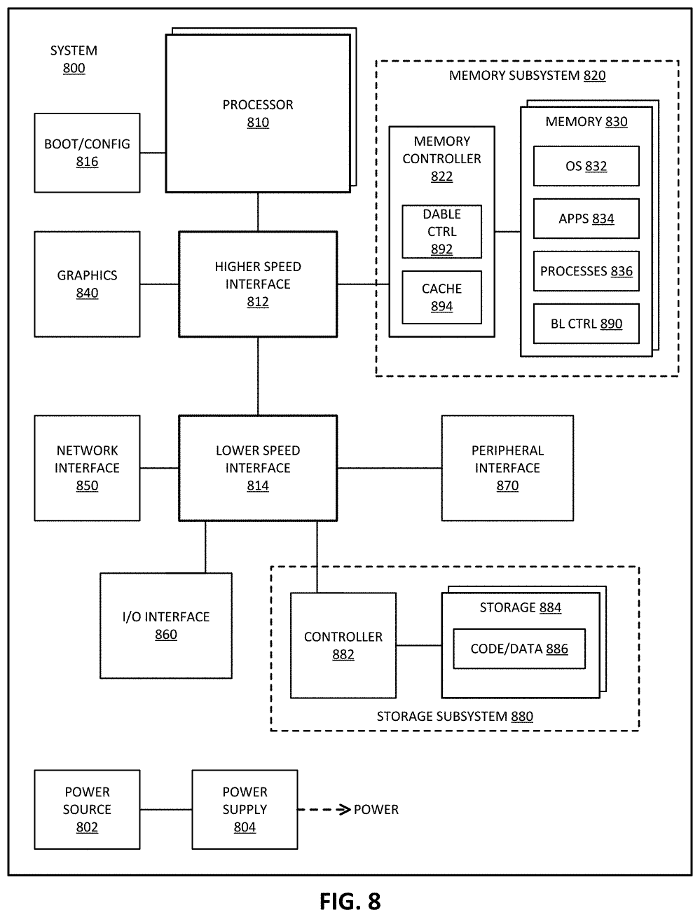

FIG. 8 is a block diagram of an example of a computing system in which dynamically adjusting burst rate can be implemented. System 800 represents a computing device in accordance with any example herein, and can be a laptop computer, a desktop computer, a tablet computer, a server, a gaming or entertainment control system, embedded computing device, or other electronic device. System 800 is a system in accordance with an example of system 100, system 200, or system 300.

In one example, memory 830 includes BL control (CTRL) 890 to control the burst length of data exchanged with memory controller 822. In one example, memory controller 822 includes cache 894 to cache ECC data for a two-operation memory access, where ECC data is stored inline. In one example, memory controller 822 includes DABLE control (CTRL) 892 to manage cache 894. DABLE control 892 can determine whether to change a burst length for the exchange of ECC data based on usage of cache 894. The determination can be in accordance with any example herein.

System 800 includes processor 810 can include any type of microprocessor, central processing unit (CPU), graphics processing unit (GPU), processing core, or other processing hardware, or a combination, to provide processing or execution of instructions for system 800. Processor 810 can be a host processor device. Processor 810 controls the overall operation of system 800, and can be or include, one or more programmable general-purpose or special-purpose microprocessors, digital signal processors (DSPs), programmable controllers, application specific integrated circuits (ASICs), programmable logic devices (PLDs), or a combination of such devices.

System 800 includes boot/config 816, which represents storage to store boot code (e.g., basic input/output system (BIOS)), configuration settings, security hardware (e.g., trusted platform module (TPM)), or other system level hardware that operates outside of a host OS. Boot/config 816 can include a nonvolatile storage device, such as read-only memory (ROM), flash memory, or other memory devices.

In one example, system 800 includes interface 812 coupled to processor 810, which can represent a higher speed interface or a high throughput interface for system components that need higher bandwidth connections, such as memory subsystem 820 or graphics interface components 840. Interface 812 represents an interface circuit, which can be a standalone component or integrated onto a processor die. Interface 812 can be integrated as a circuit onto the processor die or integrated as a component on a system on a chip. Where present, graphics interface 840 interfaces to graphics components for providing a visual display to a user of system 800. Graphics interface 840 can be a standalone component or integrated onto the processor die or system on a chip. In one example, graphics interface 840 can drive a high definition (HD) display or ultra high definition (UHD) display that provides an output to a user. In one example, the display can include a touchscreen display. In one example, graphics interface 840 generates a display based on data stored in memory 830 or based on operations executed by processor 810 or both.

Memory subsystem 820 represents the main memory of system 800, and provides storage for code to be executed by processor 810, or data values to be used in executing a routine. Memory subsystem 820 can include one or more varieties of random-access memory (RAM) such as DRAM, 3DXP (three-dimensional crosspoint), or other memory devices, or a combination of such devices. Memory 830 stores and hosts, among other things, operating system (OS) 832 to provide a software platform for execution of instructions in system 800. Additionally, applications 834 can execute on the software platform of OS 832 from memory 830. Applications 834 represent programs that have their own operational logic to perform execution of one or more functions. Processes 836 represent agents or routines that provide auxiliary functions to OS 832 or one or more applications 834 or a combination. OS 832, applications 834, and processes 836 provide software logic to provide functions for system 800. In one example, memory subsystem 820 includes memory controller 822, which is a memory controller to generate and issue commands to memory 830. It will be understood that memory controller 822 could be a physical part of processor 810 or a physical part of interface 812. For example, memory controller 822 can be an integrated memory controller, integrated onto a circuit with processor 810, such as integrated onto the processor die or a system on a chip.

While not specifically illustrated, it will be understood that system 800 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 800 includes interface 814, which can be coupled to interface 812. Interface 814 can be a lower speed interface than interface 812. In one example, interface 814 represents an interface circuit, which can include standalone components and integrated circuitry. In one example, multiple user interface components or peripheral components, or both, couple to interface 814. Network interface 850 provides system 800 the ability to communicate with remote devices (e.g., servers or other computing devices) over one or more networks. Network interface 850 can include an Ethernet adapter, wireless interconnection components, cellular network interconnection components, USB (universal serial bus), or other wired or wireless standards-based or proprietary interfaces. Network interface 850 can exchange data with a remote device, which can include sending data stored in memory or receiving data to be stored in memory.

In one example, system 800 includes one or more input/output (I/O) interface(s) 860. I/O interface 860 can include one or more interface components through which a user interacts with system 800 (e.g., audio, alphanumeric, tactile/touch, or other interfacing). Peripheral interface 870 can include any hardware interface not specifically mentioned above. Peripherals refer generally to devices that connect dependently to system 800. A dependent connection is one where system 800 provides the software platform or hardware platform or both on which operation executes, and with which a user interacts.

In one example, system 800 includes storage subsystem 880 to store data in a nonvolatile manner. In one example, in certain system implementations, at least certain components of storage 880 can overlap with components of memory subsystem 820. Storage subsystem 880 includes storage device(s) 884, which can be or include any conventional medium for storing large amounts of data in a nonvolatile manner, such as one or more magnetic, solid state, NAND, 3DXP, or optical based disks, or a combination. Storage 884 holds code or instructions and data 886 in a persistent state (i.e., the value is retained despite interruption of power to system 800). Storage 884 can be generically considered to be a “memory,” although memory 830 is typically the executing or operating memory to provide instructions to processor 810. Whereas storage 884 is nonvolatile, memory 830 can include volatile memory (i.e., the value or state of the data is indeterminate if power is interrupted to system 800). In one example, storage subsystem 880 includes controller 882 to interface with storage 884. In one example controller 882 is a physical part of interface 814 or processor 810, or can include circuits or logic in both processor 810 and interface 814.

Power source 802 provides power to the components of system 800. More specifically, power source 802 typically interfaces to one or multiple power supplies 804 in system 800 to provide power to the components of system 800. In one example, power supply 804 includes an AC to DC (alternating current to direct current) adapter to plug into a wall outlet. Such AC power can be renewable energy (e.g., solar power) power source 802. In one example, power source 802 includes a DC power source, such as an external AC to DC converter. In one example, power source 802 or power supply 804 includes wireless charging hardware to charge via proximity to a charging field. In one example, power source 802 can include an internal battery or fuel cell source.

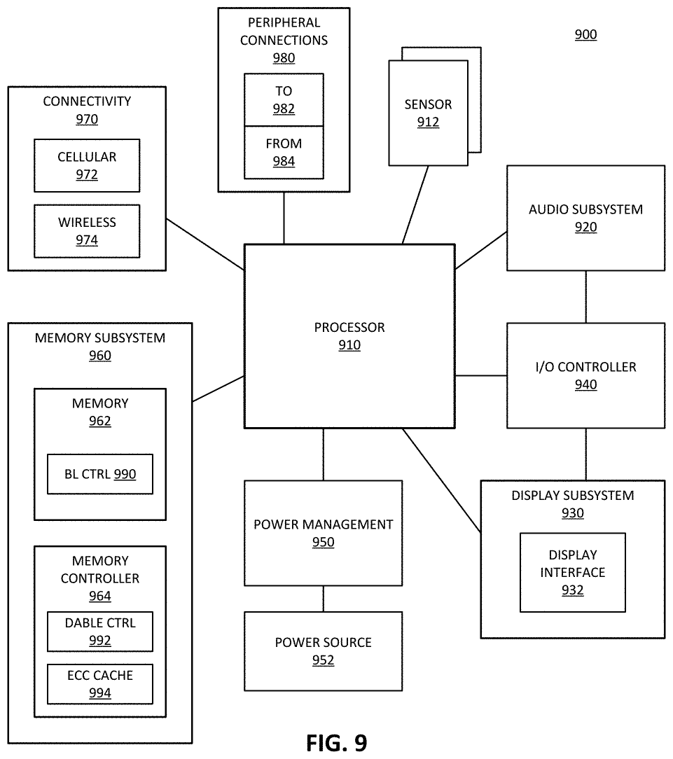

FIG. 9 is a block diagram of an example of a mobile device in which dynamically adjusting burst rate can be implemented. System 900 represents a mobile computing device, such as a computing tablet, a mobile phone or smartphone, wearable computing device, or other mobile device, or an embedded computing device. It will be understood that certain of the components are shown generally, and not all components of such a device are shown in system 900.

System 900 is a system in accordance with an example of system 100, system 200, or system 300. In one example, memory 962 includes BL control (CTRL) 990 to control the burst length of data exchanged with memory controller 964. In one example, memory controller 964 includes ECC cache 994 to cache ECC data for a two-operation memory access, where ECC data is stored inline. In one example, memory controller 964 includes DABLE control (CTRL) 992 to manage ECC cache 994. DABLE control 992 can determine whether to change a burst length for the exchange of ECC data based on usage of ECC cache 994. The determination can be in accordance with any example herein.

System 900 includes processor 910, which performs the primary processing operations of system 900. Processor 910 can be a host processor device. Processor 910 can include one or more physical devices, such as microprocessors, application processors, microcontrollers, programmable logic devices, or other processing means. The processing operations performed by processor 910 include the execution of an operating platform or operating system on which applications and device functions are executed. The processing operations include operations related to I/O (input/output) with a human user or with other devices, operations related to power management, operations related to connecting system 900 to another device, or a combination. The processing operations can also include operations related to audio I/O, display I/O, or other interfacing, or a combination. Processor 910 can execute data stored in memory. Processor 910 can write or edit data stored in memory.

In one example, system 900 includes one or more sensors 912. Sensors 912 represent embedded sensors or interfaces to external sensors, or a combination. Sensors 912 enable system 900 to monitor or detect one or more conditions of an environment or a device in which system 900 is implemented. Sensors 912 can include environmental sensors (such as temperature sensors, motion detectors, light detectors, cameras, chemical sensors (e.g., carbon monoxide, carbon dioxide, or other chemical sensors)), pressure sensors, accelerometers, gyroscopes, medical or physiology sensors (e.g., biosensors, heart rate monitors, or other sensors to detect physiological attributes), or other sensors, or a combination. Sensors 912 can also include sensors for biometric systems such as fingerprint recognition systems, face detection or recognition systems, or other systems that detect or recognize user features. Sensors 912 should be understood broadly, and not limiting on the many different types of sensors that could be implemented with system 900. In one example, one or more sensors 912 couples to processor 910 via a frontend circuit integrated with processor 910. In one example, one or more sensors 912 couples to processor 910 via another component of system 900.

In one example, system 900 includes audio subsystem 920, which represents hardware (e.g., audio hardware and audio circuits) and software (e.g., drivers, codecs) components associated with providing audio functions to the computing device. Audio functions can include speaker or headphone output, as well as microphone input. Devices for such functions can be integrated into system 900, or connected to system 900. In one example, a user interacts with system 900 by providing audio commands that are received and processed by processor 910.

Display subsystem 930 represents hardware (e.g., display devices) and software components (e.g., drivers) that provide a visual display for presentation to a user. In one example, the display includes tactile components or touchscreen elements for a user to interact with the computing device. Display subsystem 930 includes display interface 932, which includes the particular screen or hardware device used to provide a display to a user. In one example, display interface 932 includes logic separate from processor 910 (such as a graphics processor) to perform at least some processing related to the display. In one example, display subsystem 930 includes a touchscreen device that provides both output and input to a user. In one example, display subsystem 930 includes a high definition (HD) or ultra-high definition (UHD) display that provides an output to a user. In one example, display subsystem includes or drives a touchscreen display. In one example, display subsystem 930 generates display information based on data stored in memory or based on operations executed by processor 910 or both.

I/O controller 940 represents hardware devices and software components related to interaction with a user. I/O controller 940 can operate to manage hardware that is part of audio subsystem 920, or display subsystem 930, or both. Additionally, I/O controller 940 illustrates a connection point for additional devices that connect to system 900 through which a user might interact with the system. For example, devices that can be attached to system 900 might include microphone devices, speaker or stereo systems, video systems or other display device, keyboard or keypad devices, buttons/switches, or other I/O devices for use with specific applications such as card readers or other devices.

As mentioned above, I/O controller 940 can interact with audio subsystem 920 or display subsystem 930 or both. For example, input through a microphone or other audio device can provide input or commands for one or more applications or functions of system 900. Additionally, audio output can be provided instead of or in addition to display output. In another example, if display subsystem includes a touchscreen, the display device also acts as an input device, which can be at least partially managed by I/O controller 940. There can also be additional buttons or switches on system 900 to provide I/O functions managed by I/O controller 940.

In one example, I/O controller 940 manages devices such as accelerometers, cameras, light sensors or other environmental sensors, gyroscopes, global positioning system (GPS), or other hardware that can be included in system 900, or sensors 912. The input can be part of direct user interaction, as well as providing environmental input to the system to influence its operations (such as filtering for noise, adjusting displays for brightness detection, applying a flash for a camera, or other features).

In one example, system 900 includes power management 950 that manages battery power usage, charging of the battery, and features related to power saving operation. Power management 950 manages power from power source 952, which provides power to the components of system 900. In one example, power source 952 includes an AC to DC (alternating current to direct current) adapter to plug into a wall outlet. Such AC power can be renewable energy (e.g., solar power, motion based power). In one example, power source 952 includes only DC power, which can be provided by a DC power source, such as an external AC to DC converter. In one example, power source 952 includes wireless charging hardware to charge via proximity to a charging field. In one example, power source 952 can include an internal battery or fuel cell source.

Memory subsystem 960 includes memory device(s) 962 for storing information in system 900. Memory subsystem 960 can include nonvolatile (state does not change if power to the memory device is interrupted) or volatile (state is indeterminate if power to the memory device is interrupted) memory devices, or a combination. Memory 962 can store application data, user data, music, photos, documents, or other data, as well as system data (whether long-term or temporary) related to the execution of the applications and functions of system 900. In one example, memory subsystem 960 includes memory controller 964 (which could also be considered part of the control of system 900, and could potentially be considered part of processor 910). Memory controller 964 includes a scheduler to generate and issue commands to control access to memory device 962.

Connectivity 970 includes hardware devices (e.g., wireless or wired connectors and communication hardware, or a combination of wired and wireless hardware) and software components (e.g., drivers, protocol stacks) to enable system 900 to communicate with external devices. The external device could be separate devices, such as other computing devices, wireless access points or base stations, as well as peripherals such as headsets, printers, or other devices. In one example, system 900 exchanges data with an external device for storage in memory or for display on a display device. The exchanged data can include data to be stored in memory, or data already stored in memory, to read, write, or edit data.

Connectivity 970 can include multiple different types of connectivity. To generalize, system 900 is illustrated with cellular connectivity 972 and wireless connectivity 974. Cellular connectivity 972 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), 5G, or other cellular service standards. Wireless connectivity 974 refers to wireless connectivity that is not cellular, and can include personal area networks (such as Bluetooth), local area networks (such as WiFi), or wide area networks (such as WiMax), or other wireless communication, or a combination. Wireless communication refers to transfer of data through the use of modulated electromagnetic radiation through a non-solid medium. Wired communication occurs through a solid communication medium.

Peripheral connections 980 include hardware interfaces and connectors, as well as software components (e.g., drivers, protocol stacks) to make peripheral connections. It will be understood that system 900 could both be a peripheral device (“to” 982) to other computing devices, as well as have peripheral devices (“from” 984) connected to it. System 900 commonly has a “docking” connector to connect to other computing devices for purposes such as managing (e.g., downloading, uploading, changing, synchronizing) content on system 900. Additionally, a docking connector can allow system 900 to connect to certain peripherals that allow system 900 to control content output, for example, to audiovisual or other systems.

In addition to a proprietary docking connector or other proprietary connection hardware, system 900 can make peripheral connections 980 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), or other type.

In general with respect to the descriptions herein, in one example a memory controller includes: a hardware interface to couple with a memory device that has a memory array to store data and to store ECC (error checking and correction) bits for the data, wherein the memory device is to exchange data with the memory controller at either a first burst length or a second burst length longer than the first burst length; command logic to generate a data read request to read the data and a separate ECC read request to read the ECC bits; and circuitry to buffer the ECC bits in response to the ECC read request; wherein the command logic is to dynamically switch the ECC read request between the first burst length and the second burst length based on usage of the ECC cache.

In one example of the memory controller, the command logic is to dynamically switch from the first burst length to the second burst length in response to an increase in ECC cache hit rate. In accordance with any preceding example of the memory controller, in one example, the command logic is to dynamically switch from the second burst length to the first burst length in response to a decrease in ECC cache hit rate. In accordance with any preceding example of the memory controller, in one example, the command logic is to dynamically switch between the first burst length and the second burst length in response to a change in percentage of ECC read requests to total read requests. In accordance with any preceding example of the memory controller, in one example, to dynamically switch the ECC read request between the first burst length the second burst length comprises a switch between a burst length BL[N] and a burst length BL[N/2], where N is a binary number. In accordance with any preceding example of the memory controller, in one example, N equals 32 and N/2 equals 16. In accordance with any preceding example of the memory controller, in one example, the circuitry to buffer the ECC bits comprises one of: a cache device, a register file, or a buffer device. In accordance with any preceding example of the memory controller, in one example, the memory device comprises a dynamic random access memory (DRAM) device compatible with a low power double data rate (LPDDR) standard.

In general with respect to the descriptions herein, in one example a system includes: a memory device having a memory array to store data and to store ECC (error checking and correction) bits for the data; and a memory controller to exchange data with the memory device at either a first burst length or a second burst length longer than the first burst length, the memory controller including: command logic to generate a data read request to read the data and a separate ECC read request to read the ECC bits; and circuitry to buffer the ECC bits in response to the ECC read request; wherein the command logic is to dynamically switch the ECC read request between the first burst length and the second burst length based on usage of the ECC cache.

In one example of the system, wherein the command logic is to dynamically switch from the first burst length to the second burst length in response to an increase in ECC cache hit rate. In accordance with any preceding example of the system, in one example, the command logic is to dynamically switch from the second burst length to the first burst length in response to a decrease in ECC cache hit rate. In accordance with any preceding example of the system, in one example, the command logic is to dynamically switch between the first burst length and the second burst length in response to a change in percentage of ECC read requests to total read requests. In accordance with any preceding example of the system, in one example, to dynamically switch the ECC read request between the first burst length the second burst length comprises a switch between a burst length BL[N] and a burst length BL[N/2], where N is a binary number. In accordance with any preceding example of the system, in one example, the circuitry to buffer the ECC bits comprises one of: a cache device, a register file, or a buffer device. In accordance with any preceding example of the system, in one example, the memory device comprises a dynamic random access memory (DRAM) device compatible with a low power double data rate (LPDDR) standard. In accordance with any preceding example of the system, in one example, the system includes: a multicore host processor coupled to the memory controller; a display communicatively coupled to a host processor; a network interface communicatively coupled to a host processor; or a battery to power the system.

In general with respect to the descriptions herein, in one example a method for accessing ECC data includes: exchanging data between a memory controller and a memory device at either a first burst length or a second burst length longer than the first burst length, wherein the memory device has a memory array to store data and to store ECC (error checking and correction) bits for the data; generating a data read request to read the data and a separate ECC read request to read the ECC bits; and buffering ECC bits read with the ECC read request, to store ECC bits for multiple data read requests; dynamically switching the ECC read request between the first burst length and the second burst length based on usage of the ECC cache.

In one example of the method, dynamically switching from the first burst length to the second burst length comprises switching in response to an increase in ECC cache hit rate. In accordance with any preceding example of the method, in one example, dynamically switching from the first burst length to the second burst length comprises switching in response to a decrease in ECC cache hit rate. In accordance with any preceding example of the method, in one example, dynamically switching from the first burst length to the second burst length comprises switching in response to a change in percentage of ECC read requests to total read requests. In accordance with any preceding example of the method, in one example, dynamically switching the ECC read request between the first burst length the second burst length comprises switching between a burst length BL[N] and a burst length BL[N/2], where N is a binary number. In accordance with any preceding example of the method, in one example, the memory device comprises a dynamic random access memory (DRAM) device compatible with a low power double data rate (LPDDR) standard.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A memory controller, comprising:
a hardware interface to couple with a memory device that has a memory array to store data and to store ECC (error checking and correction) bits for the data, wherein the memory device is to exchange data with the memory controller at either a first burst length or a second burst length longer than the first burst length;
command logic to generate a data read request to read the data and a separate ECC read request to read the ECC bits; and
circuitry to buffer the ECC bits in response to the ECC read request;
wherein the command logic is to dynamically switch the ECC read request between the first burst length and the second burst length based on usage of the ECC cache.

2. The memory controller of claim 1, wherein the circuitry is to store the ECC bits for multiple data read requests, and wherein the command logic is to dynamically switch from the first burst length to the second burst length in response to an increase in ECC cache hit rate.

3. The memory controller of claim 1, wherein the circuitry is to store the ECC bits for multiple data read requests, and wherein the command logic is to dynamically switch from the second burst length to the first burst length in response to a decrease in ECC cache hit rate.

4. The memory controller of claim 1, wherein the command logic is to dynamically switch between the first burst length and the second burst length in response to a change in percentage of ECC read requests to total read requests.

5. The memory controller of claim 1, wherein to dynamically switch the ECC read request between the first burst length the second burst length comprises a switch between a burst length BL[N] and a burst length BL[N/2], where N is a binary number.

6. The memory controller of claim 5, wherein N equals 32 and N/2 equals 16.

7. The memory controller of claim 1, wherein the circuitry to buffer the ECC bits comprises one of: a cache device, a register file, or a buffer device.

8. The memory controller of claim 1, wherein the memory device comprises a dynamic random access memory (DRAM) device compatible with a low power double data rate (LPDDR) standard.

9. A system comprising:
a memory device having a memory array to store data and to store ECC (error checking and correction) bits for the data; and
a memory controller to exchange data with the memory device at either a first burst length or a second burst length longer than the first burst length, the memory controller including:
command logic to generate a data read request to read the data and a separate ECC read request to read the ECC bits; and
circuitry to buffer the ECC bits in response to the ECC read request;
wherein the command logic is to dynamically switch the ECC read request between the first burst length and the second burst length based on usage of the ECC cache.

10. The system of claim 9, wherein the command logic is to dynamically switch from the first burst length to the second burst length in response to an increase in ECC cache hit rate.

11. The system of claim 9, wherein the command logic is to dynamically switch from the second burst length to the first burst length in response to a decrease in ECC cache hit rate.

12. The system of claim 9, wherein the command logic is to dynamically switch between the first burst length and the second burst length in response to a change in percentage of ECC read requests to total read requests.

13. The system of claim 9, wherein to dynamically switch the ECC read request between the first burst length the second burst length comprises a switch between a burst length BL[N] and a burst length BL[N/2], where N is a binary number.

14. The system of claim 9, wherein the circuitry to buffer the ECC bits comprises one of: a cache device, a register file, or a buffer device.

15. The system of claim 9, wherein the memory device comprises a dynamic random access memory (DRAM) device compatible with a low power double data rate (LPDDR) standard.

16. The system of claim 9, further comprising one or more of:
a multicore host processor coupled to the memory controller;
a display communicatively coupled to a host processor;
a network interface communicatively coupled to a host processor; or
a battery to power the system.

17. A method for accessing ECC data, comprising:
exchanging data between a memory controller and a memory device at either a first burst length or a second burst length longer than the first burst length, wherein the memory device has a memory array to store data and to store ECC (error checking and correction) bits for the data;
generating a data read request to read the data and a separate ECC read request to read the ECC bits; and
buffering ECC bits read with the ECC read request, to store ECC bits for multiple data read requests;
dynamically switching the ECC read request between the first burst length and the second burst length based on usage of the ECC cache.

18. The method of claim 17, wherein dynamically switching from the first burst length to the second burst length comprises switching in response to an increase in ECC cache hit rate.

19. The method of claim 17, wherein dynamically switching from the first burst length to the second burst length comprises switching in response to a decrease in ECC cache hit rate.

20. The method of claim 17, wherein dynamically switching from the first burst length to the second burst length comprises switching in response to a change in percentage of ECC read requests to total read requests.

21. The method of claim 17, wherein dynamically switching the ECC read request between the first burst length the second burst length comprises switching between a burst length BL[N] and a burst length BL[N/2], where N is a binary number.

22. The method of claim 17, wherein the memory device comprises a dynamic random access memory (DRAM) device compatible with a low power double data rate (LPDDR) standard.
